(19) United States
(12) Patent Application Publication
(10) Pub. No.: US 2023/0097135 A1
(43) Pub. Date: Mar. 30, 2023

(54) ADDITIVE FOR PHOTORESIST, PHOTORESIST COMPOSITION FOR EUV INCLUDING THE SAME, AND METHOD FOR MANUFACTURING SEMICONDUCTOR DEVICE USING THE SAME

(71) Applicant: SAMSUNG ELECTRONICS CO., LTD., Suwon-si (KR)

(72) Inventors: Jin Joo KIM, Seoul (KR); Ye Chan KIM, Hwaseong-si (KR); Ju-Young KIM, Hwaseong-si (KR); Ji Yup KIM, Suwon-si (KR); Hyun Woo KIM, Seongnam-si (KR); Ju Hyeon PARK, Hwaseong-si (KR); Ji Cheol PARK, Anyang-si (KR); Hyun Ji SONG, Anyang-si (KR); Hong Gu IM, Hwaseong-si (KR); Suk Koo HONG, Suwon-si (KR)

(21) Appl. No.: 17/939,153

(22) Filed: Sep. 7, 2022

(30) Foreign Application Priority Data
Sep. 17, 2021 (KR) 10-2021-0124531

(51) Int. Cl. G03F 7/004; G03F 7/039; G03F 7/20

(52) U.S. Cl. CPC G03F 7/0045; G03F 7/0392; G03F 7/2004

(57) ABSTRACT

An additive for a photoresist, a photoresist composition for a EUV including the same, and a method for manufacturing a semiconductor device using the same, the additive including a copolymer that includes a first repeating unit represented by the following Chemical Formula 1-1, and a second repeating unit represented by the following Chemical Formula 2, wherein a molar ratio of the first repeating unit to the second repeating unit is 7:3 to 2:8,

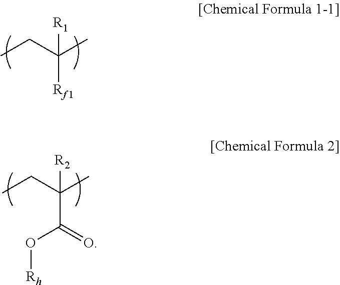

### CROSS-REFERENCE TO RELATED APPLICATION

This application claims priority to Korean Patent Application No. 10-2021-0124531, filed on Sep. 17, 2021, and all the benefits accruing therefrom under 35 U.S.C. § 119, the disclosure of which is incorporated herein by reference in its entirety.

### BACKGROUND

### 1. Field

Embodiments relate to an additive for a photoresist, a photoresist composition for a EUV including the same, and a method for manufacturing a semiconductor device using the same.

### 2. Description of the Related Art

A photolithography process using a photoresist composition may be used to form various patterns included in a semiconductor device. A photoresist film may be divided into an exposed portion and a non-exposed portion through an exposure process, and the exposed portion or the non-exposed portion may be removed through a developing process to form a photoresist pattern. Next, a desired pattern may be formed by patterning an etching target film using the photoresist pattern as an etching mask.

### SUMMARY

The embodiments may be realized by providing an additive for a photoresist, the additive comprising a copolymer including a first repeating unit represented by the following Chemical Formula 1-1, and a second repeating unit represented by the following Chemical Formula 2, wherein a molar ratio of the first repeating unit to the second repeating unit is 7:3 to 2:8,

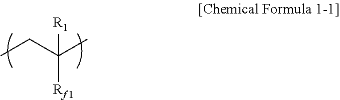

in Chemical Formula 1-1, R₁ is a hydrogen atom, a hydroxy group, or a substituted or unsubstituted alkyl group having carbon atom number of 1 to 4, and R_{f1} is a substituted or unsubstituted fluoroalkyl group or a substituted or unsubstituted fluorinated hydrocarbon group including a fluoroalkyl group as a substituent,

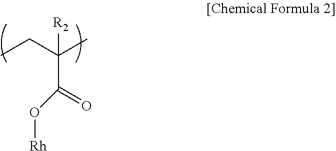

in Chemical Formula 2, R₂ is a hydrogen atom, a hydroxy group, or a substituted or unsubstituted alkyl group having carbon atom number of 1 to 4, and Rₕ is a substituted or unsubstituted hydroxyalkyl group, a substituted or unsubstituted alkoxy group, a substituted or unsubstituted cyclic ether group, a substituted or unsubstituted cyclic ester group, a substituted or unsubstituted polyoxyalkylene group, or a substituted hydrocarbon group including a hydroxyalkyl group, an alkoxy group, a cyclic ether group, a cyclic ester group, or a polyoxyalkylene group as a substituent.

The embodiments may be realized by providing an additive for a photoresist, the additive comprising a copolymer including a first repeating unit represented by the following Chemical Formula 1-2, and a second repeating unit represented by the following Chemical Formula 2,

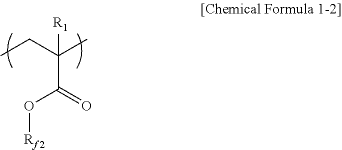

in Chemical Formula 1-2, R₁ is a hydrogen atom or a substituted or unsubstituted methyl group, and R_{f2} is an unsubstituted perfluoroalkyl group or a substituted or unsubstituted fluorinated hydrocarbon group including a perfluoroalkyl group as a substituent,

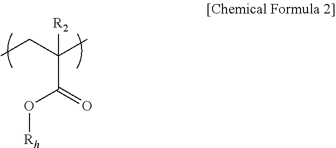

in Chemical Formula 2, R₂ is a hydrogen atom or a substituted or unsubstituted methyl group, and Rₕ is a substituted or unsubstituted hydroxyalkyl group having carbon atom number of 1 to 5, a substituted or unsubstituted polyoxyethylene group having carbon atom number of 3 to 25, or a substituted or unsubstituted γ-butyrolactonyl group.

The embodiments may be realized by providing a photoresist composition for extreme ultraviolet (EUV), the photoresist composition including a photosensitive resin; a photoacid generator; and an additive, wherein the additive includes a copolymer including a first repeating unit represented by the following Chemical Formula 1-1 and a second repeating unit represented by the following Chemical Formula 2, and a molar ratio of the first repeating unit to the second repeating unit is 7:3 to 2:8,

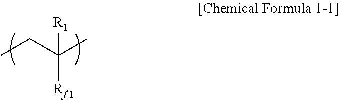

in Chemical Formula 1-1, R₁ is a hydrogen atom, a hydroxy group, or a substituted or unsubstituted alkyl group having carbon atom number of 1 to 4, and R_{f1} is an unsubstituted perfluoroalkyl group or a substituted or unsubstituted fluorinated hydrocarbon group including a perfluoroalkyl group as a substituent,

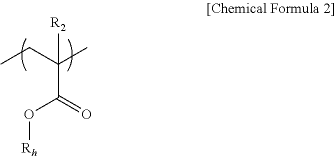

in Chemical Formula 2, R₂ is a hydrogen atom, a hydroxy group, or a substituted or unsubstituted alkyl group having carbon atom number of 1 to 4, and Rₕ is a substituted or unsubstituted hydroxyalkyl group, a substituted or unsubstituted alkoxy group, a substituted or unsubstituted cyclic ether group, a substituted or unsubstituted cyclic ester group, a substituted or unsubstituted polyoxyalkylene group, or a substituted hydrocarbon group including a hydroxyalkyl group, an alkoxy group, a cyclic ether group, a cyclic ester group, or a polyoxyalkylene group as a substituent.

### BRIEF DESCRIPTION OF THE DRAWINGS

Features will be apparent to those of skill in the art by describing in detail exemplary embodiments with reference to the attached drawings in which:

FIGS. 1 to 6 illustrate stages in a method for manufacturing the semiconductor device according to some embodiments.

### DETAILED DESCRIPTION

Additive for Photoresist

Hereinafter, an additive for a photoresist according to exemplary embodiments will be described.

The additive for a photoresist according to some embodiments may include, e.g., a copolymer having a first repeating unit and a second repeating unit.

The first repeating unit of the copolymer may be, e.g., a fluorinated repeating unit that includes a main chain including an aliphatic hydrocarbon and a side chain including a fluorinated hydrocarbon group. In an implementation, the first repeating unit may be represented by, e.g., the following Chemical Formula 1-1.

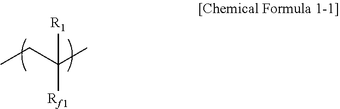

In Chemical Formula 1-1, R₁ may be or may include, e.g., a hydrogen atom, a hydroxy group, or a substituted or unsubstituted alkyl group having carbon atom number of 1 to 4. The substituted or unsubstituted alkyl group having carbon atom number of 1 to 4 may include, e.g., a methyl group, an ethyl group, an n-propyl group, an isopropyl group, an n-butyl group, a sec-butyl group, a tert-butyl group, or the like. In an implementation, R₁ may be, e.g., a hydrogen atom or a methyl group. In an implementation, R₁ may be, e.g., a methyl group. As used herein, the term “or” is not an exclusive term, e.g., “A or B” would include A, B, or A and B.

In Chemical Formula 1-1, R_{f1} may be or may include, e.g., a fluoroalkyl group or a fluorinated hydrocarbon group including a fluoroalkyl group as a substituent. In an implementation, R_{f1} may be, e.g., a perfluoroalkyl group or a fluorinated hydrocarbon group including a perfluoroalkyl group as a substituent. In an implementation, R_{f1} may be, e.g., a trifluoromethyl group or a fluorinated hydrocarbon group including a trifluoromethyl group as a substituent.

In an implementation, R_{f1} may be, e.g., a fluorinated hydrocarbon group having carbon atom number of 1 to 25 including a fluoroalkyl group as a substituent. In an implementation, R_{f1} may be, e.g., a fluorinated hydrocarbon group having carbon atom number of 1 to 15 including a perfluoroalkyl group as a substituent.

In an implementation, R_{f1} may include, e.g., one of the following substituents. In the following substituents, * represents a bonding site. In the following substituents, n represents a natural number. In an implementation, n may represent a natural number from 3 to 10.

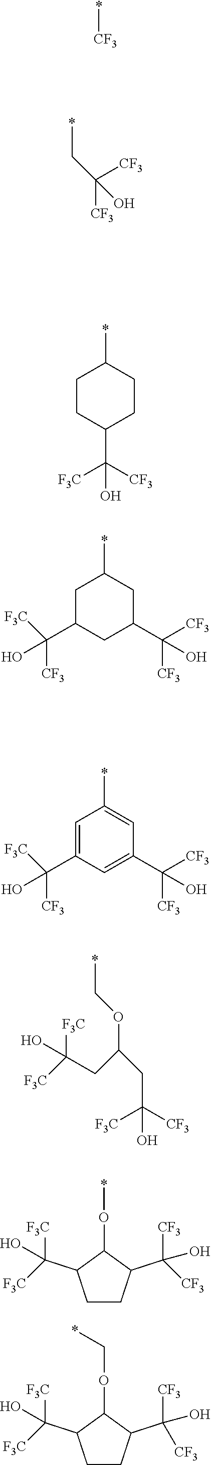

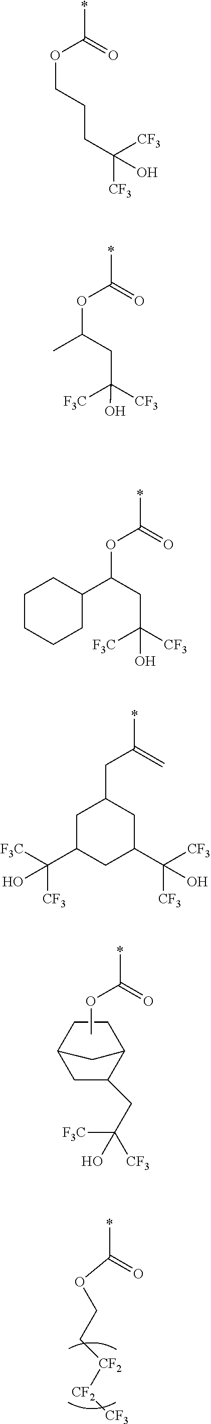

In an implementation, the first repeating unit of the copolymer may be a fluorinated acrylate repeating unit. In an implementation, the first repeating unit may be represented by, e.g., the following Chemical Formula 1-2.

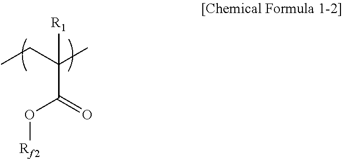

As described above with respect to the Chemical Formula 1-1, in Chemical Formula 1-2, R₁ may be or may include, e.g., a hydrogen atom, a hydroxy group, or a substituted or unsubstituted alkyl group having carbon atom number of 1 to 4.

In Chemical Formula 1-2, R_{f2} may be or may include, e.g., a fluoroalkyl group or represents a fluorinated hydrocarbon group including a fluoroalkyl group as a substituent. In an implementation, R_{f2} may be, e.g., a perfluoroalkyl group or a fluorinated hydrocarbon group including a perfluoroalkyl group as a substituent. In an implementation, R_{f2} may be, e.g., a trifluoromethyl group or a fluorinated hydrocarbon group including a trifluoromethyl group as a substituent.

In an implementation, R_{f2} may be, e.g., a fluorinated hydrocarbon group that includes at least one trifluoromethyl group and at least one hydroxy group as substituents. In an implementation, R_{f2} may be, e.g., a fluorinated hydrocarbon group having carbon atom number of 1 to 15 that includes at least one trifluoromethyl group and at least one hydroxy group as substituents. In an implementation, R_{f2} may be, e.g., a fluorinated hydrocarbon group having carbon atom number of 1 to 15 that includes 1,1,1,3,3,3-hexafluoro-2-hydroxy-2-propyl group as a substituent.

In an implementation, R_{f2} may include, e.g., one of the following substituents. In the following substituents, * represents a bonding site.

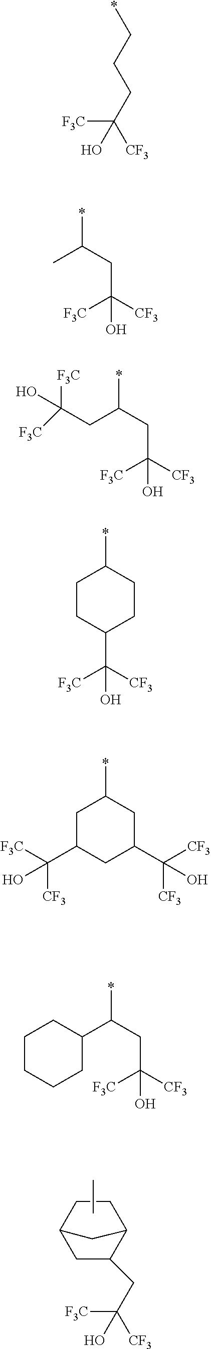

In an implementation, R_{f2} may be, e.g., a chain perfluoroalkyl group or a fluorinated hydrocarbon group including a chain perfluoroalkyl group as a substituent. In an implementation, R_{f2} may be, e.g., a chain perfluoroalkyl group having carbon atom number of 6 to 20, or a fluorinated hydrocarbon group having carbon atom umber of 7 to 25 including the chain perfluoroalkyl group having carbon atom number of 6 to 20 as a substituent.

In an implementation, R_{f2} may include, e.g., one of the following substituents. In the following substituents, * represents a bonding site. In the following substituents, n is a natural number. In an implementation, n may be, e.g., a natural number from 3 to 10.

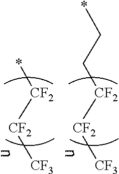

In an implementation, the first repeating unit of the copolymer may not include an aromatic hydrocarbon group. In an implementation, R_{f1} of Chemical Formula 1 and R_{f2} of Chemical Formula 2 may each be, e.g., a fluoroalkyl group or a fluorinated aliphatic hydrocarbon group including a fluoroalkyl group as a substituent.

The second repeating unit of the copolymer may be, e.g., a hydrophilic repeating unit that includes a main chain including an aliphatic hydrocarbon and a side chain including a hydrophilic functional group. In an implementation, the second repeating unit may be a hydrophilic acrylate repeating unit. In an implementation, the second repeating unit may be represented by, e.g., the following Chemical Formula 2.

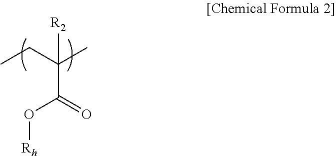

In Chemical Formula 2, R₂ may be or may include, e.g., a hydrogen atom, a hydroxy group, or a substituted or unsubstituted alkyl group having carbon atom number of 1 to 4. The substituted or unsubstituted alkyl group having carbon atom number of 1 to 4 may include, e.g., a methyl group, an ethyl group, an n-propyl group, an isopropyl group, a n-butyl group, a sec-butyl group, a tert-butyl group, and the like. In an implementation, R₂ may include, e.g., a hydrogen atom or a methyl group. In an implementation, R₂ may include, e.g., a methyl group.

In an implementation, Rₕ may be or may include, e.g., a substituted or unsubstituted hydroxyalkyl group, a substituted or unsubstituted alkoxy group, a substituted or unsubstituted cyclic ether group, a substituted or unsubstituted cyclic ester group, a substituted or unsubstituted polyoxyalkylene group, or a hydrocarbon group including a substituted or unsubstituted hydroxyalkyl group, a substituted or unsubstituted alkoxy group, a substituted or unsubstituted cyclic ether group, a substituted or unsubstituted cyclic ester group, or a substituted or unsubstituted polyoxyalkylene group as a substituent. In an implementation, Rₕ may be, e.g., a hydroxyalkyl group having carbon atom number of 1 to 10, an alkoxy group having carbon atom number of 1 to 10, a cyclic ether group having carbon atom number of 2 to 10, a cyclic ester group having carbon atom number of 2 to 10, a polyoxyalkylene group having carbon atom number of 3 to 25, or a hydrocarbon group including at least one of them as a substituent.

The hydroxyalkyl group may include, e.g., a hydroxymethyl group, a 2-hydroxyethyl group, a 2-hydroxypropyl group, a 3-hydroxypropyl group, a 2-hydroxybutyl group, a 3-hydroxybutyl group, a 4-hydroxybutyl group or the like. In an implementation, Rₕ may be, e.g., a hydroxyalkyl group having carbon atom number of 1

In an implementation, the alkoxy group may include, e.g., a methoxy group, an ethoxy group, an n-propoxy group, an isopropoxy group, an n-butoxy group, a sec-butoxy group, a tert-butoxy group, or the like. In an implementation, Rₕ may be, e.g., an alkoxy group having carbon atom number of 1 to 5.

In an implementation, the cyclic ether may include, e.g., a tetrahydrofuranyl group, a tetrahydropyranyl group, or the like. In an implementation, the cyclic ether group may be, e.g., a 2-tetrahydrofuranyl group.

In an implementation, the cyclic ester group may include, e.g., a γ-butyrolactonyl group, a γ-valerolactonyl group, a δ-valerolactonyl group, or the like. In an implementation, the cyclic ester group may include, e.g., a 2-(γ-butyrolactonyl) group or a 3-(γ-butyrolactonyl) group.

In an implementation, the polyoxyalkylene group may include, e.g., a polyoxyethylene group, a polyoxypropylene group, a polyoxybutylene group, or the like. In an implementation, the polyoxyalkylene group may include, e.g., a polyoxyethylene group having carbon atom number of 3 to 25.

In an implementation, Rₕ may include, e.g., one of the following substituents. In the following substituents, * represents a bonding site. Further, in the following substituents, m may be, e.g., a natural number. In an implementation, m may be, e.g., a natural number from 1 to 10.

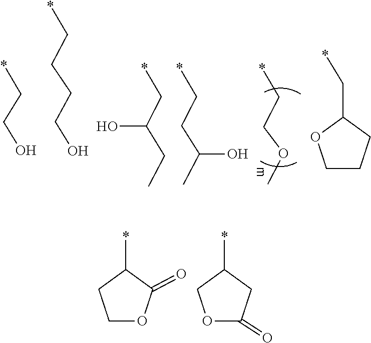

In an implementation, the second repeating unit of the copolymer may not include aromatic hydrocarbon group. In an implementation, Rₕ of Chemical Formula 2 may be, e.g., a hydroxyalkyl group, an alkoxy group, a cyclic ether group, a cyclic ester group or a polyoxyalkylene group, or may be an aliphatic hydrocarbon group including at least one of them as a substituent.

In an implementation, the second repeating unit of the copolymer may not include carboxyl group. In an implementation, Rₕ may not be a hydrogen atom (e.g., Rₕ may include at least one carbon atom).

In the copolymer of the additive for photoresist according to some embodiments, a molar ratio of the first repeating unit may be about 80% or less. In an implementation, in the copolymer, the molar ratio of the first repeating unit may be, e.g., from about 10% to about 80%. In an implementation, in the copolymer, the molar ratio of the first repeating unit may be, e.g., from about 20% to about 70%. In an implementation, in the copolymer, the molar ratio of the first repeating unit to the second repeating unit may be, e.g., from about 7:3 to about 2:8.

The copolymer of the additive for photoresist according to some embodiments may be a block copolymer or a random copolymer. In an implementation, the copolymer may be, e.g., a block copolymer.

In the additive for photoresist according to some embodiments, a weight average molecular weight Mw of the copolymer may be appropriately adjusted in consideration of a pattern resolution formed using the photoresist, a photoresist viscosity, a solvent used in the developing process of the photoresist, presence or absence of defects, or the like. In an implementation, the weight average molecular weight of the copolymer may be, e.g., about 500 to 500,000. In an implementation, the weight average molecular weight of the copolymer may be, e.g., from about 5,000 to about 15,000. In an implementation, the dispersity of the molecular weight of the copolymer may typically be, e.g., about 1.5 or less.

Photoresist Composition for EUV

Hereinafter, a photoresist composition for EUV including the additive for photoresist according to exemplary embodiments will be described.

The photoresist composition for EUV according to some embodiments may include, e.g., a photosensitive resin, a photoacid generator (PAG), an additive, and a solvent.

The photosensitive resin of the photoresist composition for EUV according to some embodiments may be a polymer that causes or undergoes a photochemical reaction by or in response to energy or light (e.g., extreme ultraviolet (EUV)). A backbone of the photosensitive resin may include, e.g., a photosensitive resin for a KrF excimer laser beam, a photosensitive resin for an ArF excimer laser, or a hybrid photosensitive resin thereof. In an implementation, the photosensitive resin may include, e.g., an acrylate, a methacrylate, an acrylic acid, a methacrylic acid, a vinyl ester, a vinyl ether, a vinyl alcohol, a vinyl halide, an olefin, a cyclic olefin, a styrene, a norbornene, a polyester, a polyamide, a polycarbonate, a maleic anhydride, an unsaturated anhydride repeating unit or a polymer, or a combination thereof as a basic chain.

The photosensitive resin may have a weight average molecular weight Mw of, e.g., about 3,000 to about 600,000. In an implementation, the photosensitive polymer may have a weight average molecular weight of, e.g., about 20,000 to about 400,000, or about 30,000 to about 300,000. The weight average molecular weight of the photosensitive polymer may be a value measured by gel permeation chromatography (GPC).

The content or amount of the photosensitive resin in the composition may be appropriately adjusted in consideration of the viscosity of the photoresist composition, the film coatability, the quality of the pattern, or the like. In an implementation, the content of the photosensitive resin (with respect to 100% by weight of the photoresist composition) may be, e.g., from about 0.1% by weight to about 40% by weight. In an implementation, the content of the photosensitive resin (with respect to 100% by weight of the photoresist composition) may be, e.g., from about 0.1% by weight to about 20% by weight.

In an implementation, the photosensitive resin may include a polymer including an acid decomposable protecting group in a side chain. The acid decomposable protecting group may be a functional group that may be separated by the photoacid generated from the photoacid generator at the time of exposure. In an implementation, in a chemically amplified positive photoresist process, the acid decomposable protecting group of the photosensitive resin may break away by a chained chemical reaction with photoacid during a post-exposure baking process. Accordingly, the exposed portion of the photoresist may change to a state of being easily dissolvable in the developer.

The acid decomposable protecting group may include, e.g., cyclic aliphatic hydrocarbon group having carbon atom number of 6 to 20, such as substituted or unsubstituted adamantyl, substituted or unsubstituted tricyclodecanyl, substituted or unsubstituted novinyl, substituted or unsubstituted isobornyl, substituted or unsubstituted cyclopentyl, or substituted or unsubstituted cyclohexyl. In an implementation, examples of the acid decomposable protecting group may include tert-butyl, tetrahydropyranyl, tetrahydrofuranyl, ethoxyethyl, or the like. These may be used alone or in combination of two or more.

The photoacid generator of the photoresist composition for EUV according to some embodiments may generate photoacid by or in response to exposure to a beam or light (e.g., extreme ultraviolet (EUV)). In an implementation, the photoacid generator may include, e.g., onium salt, aromatic diazonium salt, sulfonium salt, triarylsulfonium salt, diarylsulfonium salt, monoarylsulfonium salt, iodonium salt, diaryliodonium salt, nitrobenzyl ester, disulfone, diazo-disulfone, sulfonate, trichloromethyl triazine, N-hydroxysuccinimide triplate, or combinations thereof.

In an implementation, the photoacid generator may include, e.g., phthalimido trifluoromethane sulfonate, dinitrobenzyl tosylate, n-decyldisulfone, naphthylimido trifluoromethane sulfonate, diphenyliodonium hexafluorophosphate, diphenyliodonium hexachlorofluoroarsenate, diphenyliodonium hexafluoro antimonate, diphenylparamethoxyphenyl triflate, diphenyl paratoluenyl triflate, triphenylsulfonium triflate, dibutyl naphthyl sulfonium triplate, or combinations thereof.

The content of the photoacid generator (in the composition) may be appropriately adjusted in consideration of the quality of the pattern or the like. In an implementation, the content of the photoacid generator (with respect to 100% by weight of the photosensitive resin) may be, e.g., from about 0.001% by weight to about 20% by weight. If the content of the photoacid generator were to be less than about 0.01% by weight, the sensitivity to energy (e.g., EUV) may decrease. If the content of the photoacid generator were to exceed about 20% by weight, the photoacid generator may excessively absorb energy, and the quality of the pattern may deteriorate. In an implementation, the content of the photoacid generator may be, e.g., from about 0.01% by weight to about 10% by weight.

The additive of the photoresist composition for EUV according to some embodiments may help improve the dissolution rate of the photoresist with respect to water or an aqueous alkaline developer. Additives may include the copolymer described above according to some embodiments. In an implementation, the additive may include, e.g., the copolymer that has the first repeating unit represented by Chemical Formula 1-1 or Chemical Formula 1-2 and the second repeating unit represented by Chemical Formula 2.

The content of the additive (in the composition) may be appropriately adjusted in consideration of the quality of the pattern and the like. In an implementation, the content of the additive (with respect to 100% by weight of the photoresist composition) may be, e.g., from about 0.001% by weight to about 5% by weight. In an implementation, the content of the additive may be, e.g., from about 0.01% by weight to about 1% by weight. In an implementation, the content of the additive may be, e.g., from about 0.01% by weight to about 10% by weight.

In an implementation, the content of the additive (with respect to 100% by weight of a solid content of the photoresist composition) may be, e.g., from about 0.1% by weight to about 20% by weight. In an implementation, the content of the additive (with respect to 100% by weight of a solid content of the photoresist composition) may be, e.g., from about 1% by weight to about 10% by weight. Within the content range, the additive may sufficiently improve the dissolution rate of the photoresist with respect to water or an alkaline developer. This makes it possible to help prevent defects of pattern that may occur due to an incomplete removal or a reattachment of the photoresist in the developing process.

The solvent of the photoresist composition for EUV according to some embodiments may dissolve the photosensitive resin or the like. In an implementation, the solvent may include, e.g., ketones such as acetone, methyl ethyl ketone, cyclohexanone, methyl isoamyl ketone and 2-heptanone; polyhydirc alcohols and their derivatives such as ethylene glycol, ethylene glycol monoacetate, diethylene glycol, diethylene glycol monoacetate, propylene glycol, propylene glycol monoacetate, dipropylene glycol, monomethyl ether of dipropylene glycol monoacetate, monoethyl ether, monopropyl ether, and monophenyl ether; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethyl ethoxyacetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanoate, 3-methoxybutyl acetate, and 3-methyl-3-methoxybutyl acetate; or aromatic hydrocarbons such as toluene and xylene.

In an implementation, the photoresist composition for EUV according to some embodiments may further include a photo decomposable quencher (PDQ) (hereinafter, quencher). The quencher may help improve the uniformity and flatness of the photoresist film after the post-exposure baking process.

In an implementation, the quencher may include, e.g., hydrogen chloride, ethyl, ester, alcohol, water, fluorine compound, cyanide, ketone, bromide, iodide, amines, aldehyde, phenol, nitro compounds, or combinations thereof.

The content of the quencher may be appropriately adjusted in consideration of the quality of the pattern and the like. In an implementation, the content of the quencher (with respect to 100% by weight of the photosensitive resin) may be, e.g., from about 0.001% by weight to about 20% by weight. In an implementation, the content of the quencher may be, e.g., from about 0.01% by weight to about 10% by weight.

Method for Manufacturing Semiconductor Device

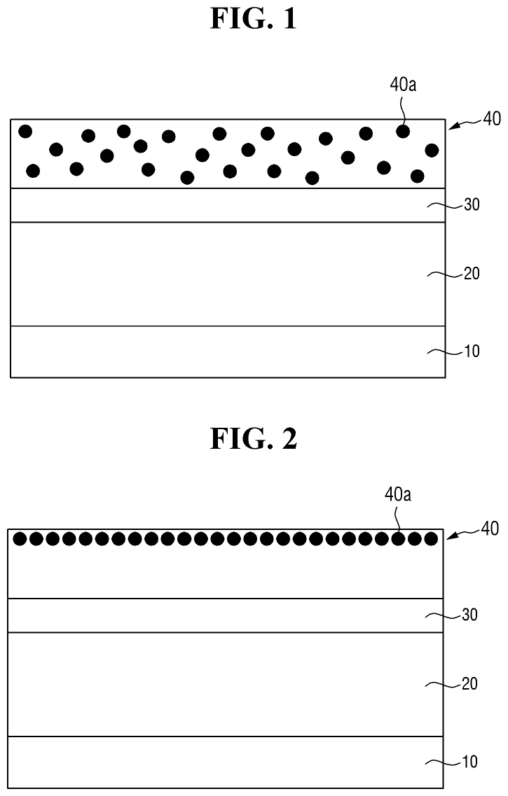

Hereinafter, a method for manufacturing a semiconductor device using the composition for EUV photoresist according to exemplary embodiments will be described referring to FIGS. 1 to 6.

FIGS. 1 to 6 illustrate stages in a method for manufacturing the semiconductor device according to some embodiments.

Referring to FIG. 1, a substrate 10 may be provided. Subsequently, a target film 20, a mask film 30, and a photoresist film 40 may be sequentially formed on the substrate 10.

The substrate 10 may be bulk silicon or silicon-on-insulator (SOI). The substrate 10 may be a silicon substrate, or may include other materials, e.g., silicon germanium, gallium arsenide, silicon germanium on insulator (SGOI), indium antimonide, lead tellurium compounds, indium arsenide, indium phosphide, gallium arsenide, or gallium antimonide. In an implementation, the substrate 10 may have an epitaxial layer formed on the base substrate, or may be a ceramic substrate, a quartz substrate, a glass substrate for a display, or the like.

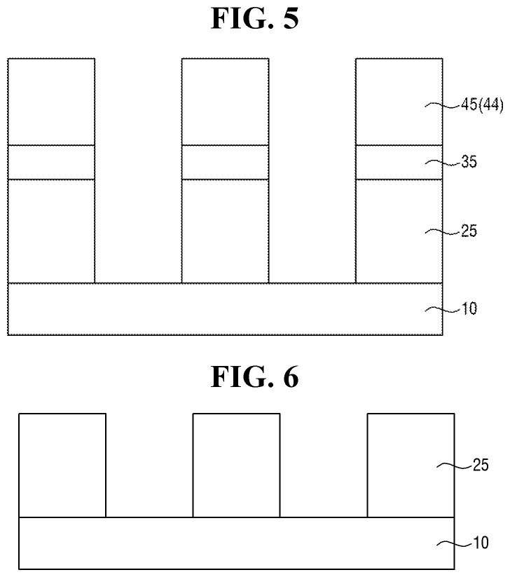

The target film 20 may be formed on the substrate 10. The target film 20 may be a layer in which an image is transferred from a photoresist pattern (e.g., 45 of FIG. 4) to be described below and formed into a predetermined target pattern (e.g., 25 of FIG. 5).

In an implementation, the target film 20 may include a conductive material such as a metal, a metal nitride, a metal silicide, or a metal silicide nitride film. In an implementation, the target film 20 may include an insulating material such as silicon oxide, silicon nitride, and silicon oxynitride. In an implementation, the target film 20 may include a semiconductor material such as polysilicon.

The mask film 30 may be formed on the target film 20. The mask film 30 may be formed by, e.g., applying it on the target film 20 by a spin coating process and then performing a baking process. The mask film 30 may include, e.g., a spin-on hard mask (SOH).

The photoresist film 40 may be formed on the mask film 30. The photoresist film 40 may be applied onto the mask film 30 by, e.g., an application process such as a spin coating process, a dip coating process, or a spray coating.

The photoresist film 40 may include an additive 40a. The additive 40a may include the copolymer described above according to some embodiments. In an implementation, the additive may include, e.g., a copolymer that has the first repeating unit represented by Chemical Formula 1-1 or Chemical Formula 1-2 and the second repeating unit represented by Chemical Formula 2.

The photoresist film 40 may include or be prepared from a photoresist composition for EUV. In an implementation, the photoresist film 40 may include, e.g., the photosensitive resin, the photoacid generator, the additive 40a, and the solvent.

Referring to FIG. 2, a first baking process may be performed on the photoresist film 40.

The first baking process may include, e.g., a pre-curing process such as a post-application baking process performed at a temperature of about 50° C. to about 300° C. As the first baking process is performed, the solvent in the photoresist film 40 may be volatilized, and the adhesiveness between the mask film 30 and the photoresist film 40 may be enhanced.

Further, as the first baking process is performed, the additive 40a may be self-segregated to a surface of the photoresist film 40. In an implementation, the additive 40a may have a relatively low surface energy (e.g., about 40 mN/m or less) as compared to other constituent components of the photoresist film 40, by including the first repeating unit which is the fluorinated repeating unit. In an implementation, as the first baking process is performed, the additive 40a may be intensively or densely distributed on the surface of the photoresist film 40 (e.g., the upper surface of the photoresist film 40).

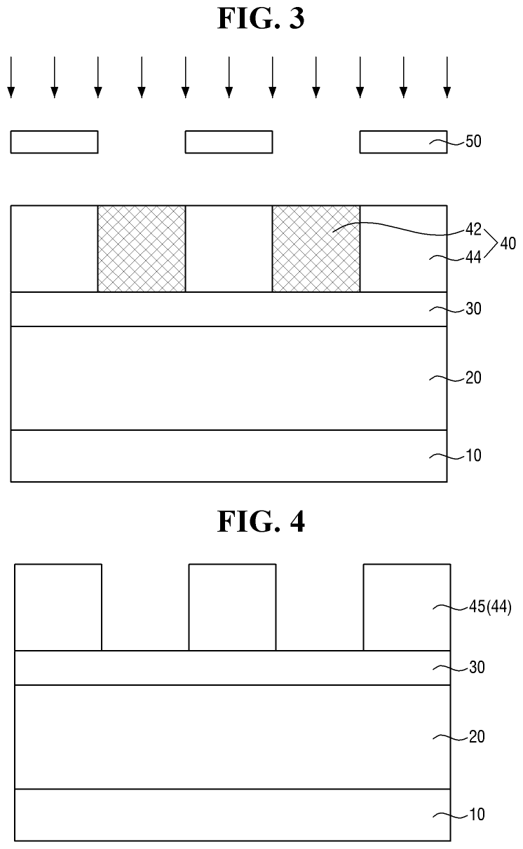

Referring to FIG. 3, an exposure process may be performed on the photoresist film 40.

The photoresist film 40 may be divided into an exposed portion 42 and a non-exposed portion 44 by the exposure process. In an implementation, an exposure mask 50 may be placed on the photoresist film 40. When a light or energy beam (e.g., EUV) is irradiated from the upper part of the exposure mask 50 from a beam source, the beam that has passed through a transmission part of the exposure mask 50 may be irradiated to a part of the photoresist film 40 to form the exposed portion 42. The other part of the photoresist film 40 that is not irradiated with beam due to a shielding portion of the exposure mask 50 may form the non-exposed portion 44.

The beam may be, e.g., a KrF excimer laser beam, an ArF excimer laser beam, or an extreme ultraviolet (EUV) beam. In an implementation, the beam may be the extreme ultraviolet (EUV) beam.

In an implementation, a second baking process may be performed on the photoresist film 40, after the exposure process has been performed. The second baking process may include, e.g., a pre-curing process such as a post-exposure baking process performed at a temperature of about 50° C. to about 300° C. As the second baking process is performed, the solubility of the exposed portion 42 may be made higher than the solubility of the non-exposed portion 44. In an implementation, the photosensitive resin of the exposed portion 42 may undergo a chain chemical reaction by the photoacid generated from the photoacid generator.

Referring to FIGS. 3 and 4, a developing process may be performed to form a photoresist pattern 45 from the photoresist film 40.

In an implementation, a positive tone development (PTD) process may be performed. In an implementation, by the exposure process, the solubility of the exposed portion 42 to the developer may be made higher than the solubility of the non-exposed portion 44. As a result, the exposed portion 42 may be dissolved in the developer and removed in the developing process. The developer may include, e.g., a hydrophilic developer such as deionized water, an alcohol solution, or a hydroxide solution such as tetra methyl ammonium hydroxide (TMAH). The non-exposed portion 44 may remain in the developing process to form the photoresist pattern 45.

In the developing process, the additive 40a may help improve the dissolution rate of the exposed portion 42 of the photoresist film 40. In an implementation, the additive 40a may have a high dissolution rate with respect to a hydrophilic developer, by including the second repeating unit which is a hydrophilic repeating unit. In an implementation, as described above, the additive 40a may be distributed on the surface of the photoresist film 40, and the second repeating unit of the additive 40a may be exposed to the surface of the photoresist film 40. As a result, the surface hydrophilicity of the photoresist film 40 may be enhanced, and the dissolution rate to the hydrophilic developer may be improved.

As the design rules of the semiconductor devices are gradually reduced, an extreme ultraviolet lithography process that utilizes extreme ultraviolet (EUV) having short wavelength as beam may be utilized. In such an extreme ultraviolet lithography process, a precise development may be required to form a fine pattern, and a control of defect caused by the developing process has been considered. In some photoresists, the dissolution rate to the hydrophilic developer could be insufficient (particularly at an interface between the exposed portion and the non-exposed portion) and the photoresist may not be developed precisely in the developing process.

In the method for manufacturing a semiconductor device according to some embodiments, defects due to the developing process may be reduced, by utilizing the photoresist composition for EUV including the additive 40a. In an implementation, as described above, the copolymer of the additive 40a may include the first repeating unit which is a fluorinated repeating unit, and the second repeating unit which is a hydrophilic repeating unit, and the surface hydrophilicity may be strengthened and the dissolution rate to the hydrophilic developer may be improved. This makes it possible to provide a method for manufacturing a semiconductor device in which defects due to the developing process are reduced and a precise development is facilitated.

In an implementation, in the copolymer of the additive 40a, the molar ratio of the first repeating unit may be, e.g., about 80% or less. When the molar ratio of the first repeating unit in the copolymer is about 80% or less, the additive 40a may have further enhanced surface hydrophilicity. In an implementation, the molar ratio of the first repeating unit in the copolymer may be, e.g., from about 10% to about 80%. If the molar ratio of the first repeating unit in the copolymer were to be less than about 10%, the surface energy of the additive 40a may increase, and the additive 40a may not be easily self-segregated to the surface of the photoresist film 40. If the molar ratio of the first repeating unit in the copolymer were to exceed about 80%, the additive 40a may not satisfy the surface hydrophilicity for a precise developing process. In an implementation, the molar ratio of the first repeating unit in the copolymer may be, e.g., from about 20% to about 70%. In an implementation, in the copolymer, the molar ratio of the first repeating unit to the second repeating unit may be, e.g., from about 7:3 to about 2:8.

In an implementation, the copolymer of the additive 40a may be a block copolymer or a random copolymer. In an implementation, the copolymer may be a block copolymer. When the copolymer is a block copolymer, the additive 40a may be more easily self-segregated to the surface of the photoresist film 40.

In an implementation, the first repeating unit of the copolymer and the second repeating unit of the copolymer may each not include an aromatic hydrocarbon group. If the first repeating unit or the second repeating unit were to include an aromatic hydrocarbon group, the additive 40a may not satisfy the surface hydrophilicity for the precise developing process.

In an implementation, the second repeating unit of the copolymer may not include carboxyl group. If the second repeating unit were to include a carboxyl group, the additive 40a may not be easily self-segregated to the surface of the photoresist film 40.

Referring to FIG. 5, the target film 20 may be patterned, using the photoresist pattern 45 as an etching mask.

In an implementation, the mask pattern 35 and the target pattern 25 may be formed by performing an etching process on the mask film 30 and the target film 20, using the photoresist pattern 45 as an etching mask. The etching process may include a dry etching process or a wet etching process, depending on the substance constituting the target film 20, the etching selectivity between the photoresist pattern 45 and the target film 20, or the like.

Referring to FIG. 6, the mask pattern 35 and the photoresist pattern 45 may be removed.

The mask pattern 35 and the photoresist pattern 45 may be removed, e.g., by an ashing process and/or a strip process.

As a result, the target pattern 25 may be formed on the substrate 10. When the target film 20 includes a conductive material, the target pattern 25 may form a predetermined conductive pattern. When the target film 20 includes an insulating material, the target pattern 25 may form a predetermined insulating pattern. When the target film 20 includes a semiconductor material, the target pattern 25 may form a predetermined semiconductor pattern.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

A copolymer additive for a photoresist according to some embodiments may be manufactured by a copolymerization reaction that uses a monomer corresponding to the first repeating unit and a monomer corresponding to the second repeating unit.

A first monomer represented by the following Structural Formula 1-1 was used as the monomer corresponding to the first repeating unit, and a second monomer represented by the following Structural Formula 1-2 was used as the monomer corresponding to the second repeating unit.

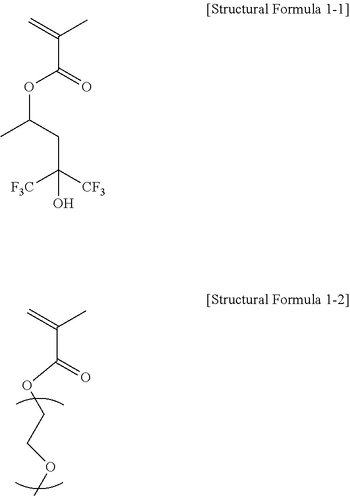

The first monomer to the second monomer were mixed at a molar ratio of 5:5 using PGMEA (propylene glycol methyl ether acetate) as a solvent, and radical polymerization reaction was performed at ambient temperature for 1 day, using AIBN (azobisisobutyronitrile) as an initiator. Next, the polymerization reaction result was precipitated three times using an n-hexane solution and dried. As a result, a copolymer represented by the following Structural Formula 1-3 was manufactured.

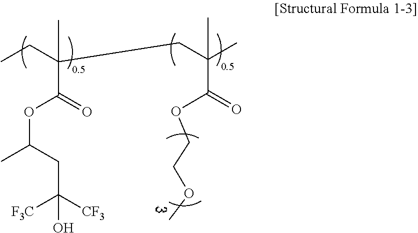

A photoresist composition was manufactured, using poly (hydroxystyrene-co-propylcyclopentylmethacrylate) as the photosensitive resin, using triphenylsulfonium difluoromethylsulfonate as the photoacid generator, using the copolymer represented by the Structural Formula 1-3 as the additive, and using propylene glycol methyl ether acetate and propylene glycol metal ether as the solvent.

1.05 parts by weight of poly (hydroxystyrene-co-propylcyclopentylmethacrylate) was used with respect to 100 parts by weight of the photoresist composition. Further, 0.3 part by weight of triphenylsulfonium difluoromethylsulfonate and 0.05 parts by weight of the copolymer represented by the Structural Formula 1-3 were used, with respect to 1 part by weight of poly (hydroxystyrene-co-propylcyclopentylmethacrylate).

### Example 2

A photoresist composition was manufactured in the manner similar to Example 1 except that a copolymer manufactured by mixing the first monomer and the second monomer at a molar ratio of 2:8 was used as the additive.

### Example 3

The photoresist composition was manufactured in the manner similar to Example 1, except that a copolymer manufactured by mixing the first monomer and the second monomer at a molar ratio of 1:9 was used as the additive.

### Comparative Example 1

The photoresist composition was manufactured in the manner similar to Example 1, except that a copolymer manufactured by mixing the first monomer and the second monomer at a molar ratio of 9:1 was used as the additive.

### Comparative Example 2

A photoresist composition was manufactured in the manner similar to Example 1, except that the additive was omitted.

Evaluation

A photoresist film was formed using the photoresist compositions according to Examples 1 to 3 and Comparative Examples 1 and 2, and a contact angle of water with respect to the formed photoresist film was evaluated, and shown in Table 1 below. The photoresist film was formed, using the method for manufacturing a semiconductor device described above using FIGS. 1 and 2.

TABLE 1

| | Contact angle (°) | | | | |
|---|---|---|---|---|---|
| SAMPLE | 1 | 2 | 3 | 4 | Average |
| Example 1 | 92.4 | 92.7 | 92.6 | 92.3 | 92.5 |
| Example 2 | 91.3 | 90.9 | 90.2 | 89.8 | 90.6 |
| Example 3 | 90.6 | 90.7 | 88.9 | 89.3 | 89.9 |
| Comparative | 99.7 | 99.5 | 99.2 | 98.1 | 99.2 |
| example 1 | | | | | |
| Comparative | 93.7 | 93.8 | 89.6 | 90.4 | 91.9 |
| example 2 | | | | | |

Referring to Table 1, it may be seen that the photoresist composition according to Examples 1 to 3 exhibited a considerably small contact angle to water, as compared with the photoresist composition according to Comparative Example 1 including the first repeating unit (which is a fluorinated repeating unit) at a higher molar ratio. In particular, in Examples 1 to 3, it may be seen that the photoresist composition exhibited a smaller contact angle as the molar ratio of the second monomer increased. Accordingly, it may be seen that the additive for photoresist according to the Examples exhibited enhanced surface hydrophilicity, by including the molar ratio of the second repeating unit, which is a hydrophilic repeating unit, at a relatively high rate.

Further, referring to Table 1, it may be seen that the photoresist composition according to Examples 1 to 3 still exhibited a similar level of contact angle as compared with the photoresist composition according to Comparative Example 2 in which no additive is used. Therefore, it may be seen that the additive for photoresist according to the Examples exhibited enhanced surface hydrophilicity, by including the second repeating unit which is a hydrophilic repeating unit, even though it includes the first repeating unit which is a fluorinated repeating unit.

By way of summation and review, as design rules of the semiconductor device are gradually reduced, a technique may be used to form a pattern having a smaller size. To form a smaller pattern, an extreme ultraviolet lithography process that utilizes extreme ultraviolet (EUV) of a short wavelength as beam may be used. In a mass production process of nano-class semiconductor devices of 40 nm or less, extreme ultraviolet having a wavelength of about 10 nm to about 14 nm may be used.

One or more embodiments may provide an additive for a photoresist that reduces defects during a developing process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An additive for a photoresist, the additive comprising a copolymer including:
a first repeating unit represented by the following Chemical Formula 1-1, and
a second repeating unit represented by the following Chemical Formula 2,
wherein:
a molar ratio of the first repeating unit to the second repeating unit is 7:3 to 2:8, 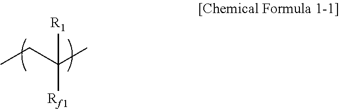
in Chemical Formula 1-1,
R₁ is a hydrogen atom, a hydroxy group, or a substituted or unsubstituted alkyl group having carbon atom number of 1 to 4, and
R_{f1} is a substituted or unsubstituted fluoroalkyl group or a substituted or unsubstituted fluorinated hydrocarbon group including a fluoroalkyl group as a substituent, 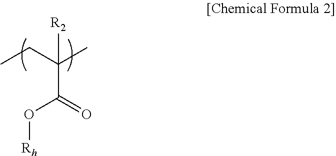
in Chemical Formula 2,
R₂ is a hydrogen atom, a hydroxy group, or a substituted or unsubstituted alkyl group having carbon atom number of 1 to 4, and
Rₕ is a substituted or unsubstituted hydroxyalkyl group, a substituted or unsubstituted alkoxy group, a substituted or unsubstituted cyclic ether group, a substituted or unsubstituted cyclic ester group, a substituted or unsubstituted polyoxyalkylene group, or a substituted hydrocarbon group including a hydroxyalkyl group, an alkoxy group, a cyclic ether group, a cyclic ester group, or a polyoxyalkylene group as a substituent.

2. The additive for photoresist as claimed in claim 1, wherein R₁ is a hydrogen atom or an unsubstituted methyl group.

3. The additive for photoresist as claimed in claim 1, wherein R_{f1} is an unsubstituted perfluoroalkyl group or a substituted or unsubstituted fluorinated hydrocarbon group including a perfluoroalkyl group as a substituent.

4. The additive for photoresist as claimed in claim 1, wherein:
the first repeating unit is represented by the following Chemical Formula 1-2: 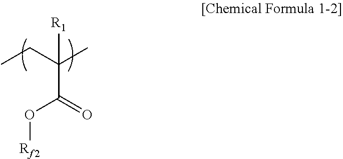
in Chemical Formula 1-2,
R₁ is a hydrogen atom, a hydroxy group, or a substituted or unsubstituted alkyl group having carbon atom number of 1 to 4, and
R_{f2} is an unsubstituted perfluoroalkyl group or a substituted or unsubstituted fluorinated hydrocarbon group including a perfluoroalkyl group as a substituent.

5. The additive for photoresist as claimed in claim 1, wherein R₂ is a hydrogen atom or an unsubstituted methyl group.

6. The additive for photoresist as claimed in claim 1, wherein Rₕ is a substituted or unsubstituted hydroxyalkyl group having carbon atom number of 1 to 5, a substituted or unsubstituted polyoxyethylene group having carbon atom number of 3 to 25, or a substituted or unsubstituted γ-butyrolactonyl group.

7. The additive for photoresist as claimed in claim 1, wherein:
the first repeating unit does not include an aromatic hydrocarbon group, and
the second repeating unit does not include an aromatic hydrocarbon group.

8. The additive for photoresist as claimed in claim 1, wherein the second repeating unit does not include a carboxyl group.

9. The additive for photoresist as claimed in claim 1, wherein a weight average molecular weight of the copolymer is 5,000 to 15,000.

10. The additive for photoresist as claimed in claim 9, wherein a dispersity of molecular weight of the copolymer is 1.5 or less.

11. An additive for a photoresist, the additive comprising a copolymer including:
a first repeating unit represented by the following Chemical Formula 1-2, and
a second repeating unit represented by the following Chemical Formula 2, 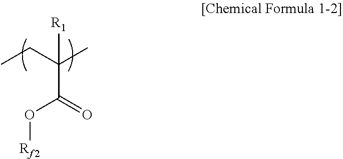
in Chemical Formula 1-2,
R₁ is a hydrogen atom or a substituted or unsubstituted methyl group, and
R_{f2} is an unsubstituted perfluoroalkyl group or a substituted or unsubstituted fluorinated hydrocarbon group including a perfluoroalkyl group as a substituent, 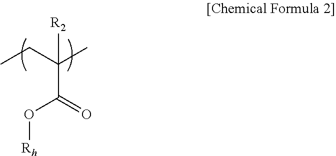
in Chemical Formula 2,
R₂ is a hydrogen atom or a substituted or unsubstituted methyl group, and
Rₕ is a substituted or unsubstituted hydroxyalkyl group having carbon atom number of 1 to 5, a substituted or unsubstituted polyoxyethylene group having carbon atom number of 3 to 25, or a substituted or unsubstituted γ-butyrolactonyl group.

12. The additive for photoresist as claimed in claim 11, wherein a molar ratio of the first repeating unit to the second repeating unit is 7:3 to 2:8.

13. The additive for photoresist as claimed in claim 11, wherein R_{f2} is a substituted or unsubstituted fluorinated hydrocarbon group including 1,1,1,3,3,3-hexafluoro-2-hydroxy-2-propyl group as a substituent.

14. The additive for photoresist as claimed in claim 11, wherein R_{f2} is an unsubstituted chain perfluoroalkyl group having carbon atom number of 6 to 20 or a substituted or unsubstituted fluorinated hydrocarbon group including a chain perfluoroalkyl group having carbon atom number of 6 to 20 as a substituent.

15. The additive for photoresist as claimed in claim 11, wherein:
the first repeating unit does not include an aromatic hydrocarbon group, and
the second repeating unit does not include an aromatic hydrocarbon group.

16. The additive for photoresist as claimed in claim 11, wherein the second repeating unit does not include a carboxyl group.

17. A photoresist composition for extreme ultraviolet (EUV), the photoresist composition comprising:
a photosensitive resin;
a photoacid generator; and
an additive,
wherein:
the additive includes a copolymer including a first repeating unit represented by the following Chemical Formula 1-1 and a second repeating unit represented by the following Chemical Formula 2, and
a molar ratio of the first repeating unit to the second repeating unit is 7:3 to 2:8, 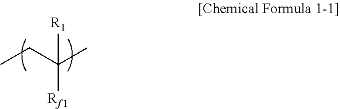
in Chemical Formula 1-1,
R₁ is a hydrogen atom, a hydroxy group, or a substituted or unsubstituted alkyl group having carbon atom number of 1 to 4, and
R_{f1} is an unsubstituted perfluoroalkyl group or a substituted or unsubstituted fluorinated hydrocarbon group including a perfluoroalkyl group as a substituent, 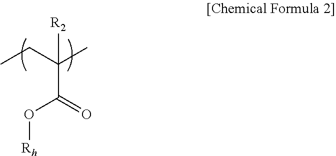
in Chemical Formula 2,
R₂ is a hydrogen atom, a hydroxy group, or a substituted or unsubstituted alkyl group having carbon atom number of 1 to 4, and
Rₕ is a substituted or unsubstituted hydroxyalkyl group, a substituted or unsubstituted alkoxy group, a substituted or unsubstituted cyclic ether group, a substituted or unsubstituted cyclic ester group, a substituted or unsubstituted polyoxyalkylene group, or a substituted hydrocarbon group including a hydroxyalkyl group, an alkoxy group, a cyclic ether group, a cyclic ester group, or a polyoxyalkylene group as a substituent.

18. The photoresist composition for EUV as claimed in claim 17, wherein the photoresist composition includes the additive in an amount of 1% by weight to 10% by weight with respect to a total weight of a solid content of the photoresist composition for EUV.

19. The photoresist composition for EUV as claimed in claim 17, wherein:
the first repeating unit is represented by the following Chemical Formula 1-2, 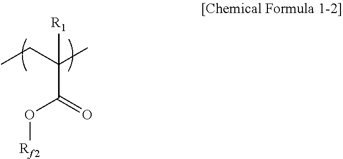
in Chemical Formula 1-2,
R₁ is a hydrogen atom, a hydroxy group, or a substituted or unsubstituted alkyl group having carbon atom number of 1 to 4, and
R_{f2} is an unsubstituted perfluoroalkyl group or a substituted or unsubstituted fluorinated hydrocarbon group including a perfluoroalkyl group as a substituent.

20. The photoresist composition for EUV as claimed in claim 17, wherein Rₕ is a substituted or unsubstituted hydroxyalkyl group having carbon atom number of 1 to 5, a substituted or unsubstituted polyoxyethylene group having carbon atom number of 3 to 25, or a substituted or unsubstituted γ-butyrolactonyl group.
